(19) United States
(12) Patent Application Publication
(10) Pub. No.: US 2026/0190407 A1
(43) Pub. Date: Jul. 2, 2026

(54) SEMICONDUCTOR STRUCTURE AND MANUFACTURING METHOD THEREOF

(71) Applicant: Enkris Semiconductor, Inc., Suzhou (CN)

(72) Inventors: Jiaqi HE, Suzhou (CN); Kai CHENG, Suzhou (CN)

(21) Appl. No.: 19/243,503

(22) Filed: Jun. 19, 2025

(30) Foreign Application Priority Data
Jan. 2, 2025 (CN) 202510018422.X

(51) Int. Cl. H10D 62/10; H10D 30/01; H10D 30/47; H10D 62/85; H10D 64/27

(52) U.S. Cl. CPC H10D 62/126; H10D 30/015; H10D 30/471; H10D 62/102; H10D 64/513; H10D 62/8503

(57) ABSTRACT

A semiconductor structure includes a substrate, a channel layer, and a barrier layer that are stacked in sequence; multiple first P-type semiconductor layers, and multiple second P-type semiconductor layers. The channel layer and the barrier layer form a heterojunction. The heterojunction includes a gate region, and a source region and a drain region located on two sides of the gate region. The first P-type semiconductor layers are spaced apart along a first direction and located in the gate region, where the first direction is the extension direction of the gate region. The second P-type semiconductor layers are arranged along the first direction and located between the gate region and the drain region. The first P-type semiconductor layers and the second P-type semiconductor layers alternate along the first direction.

### CROSS-REFERENCE TO RELATED APPLICATION(S)

This application claims priority to Chinese Patent Application No. 202510018422.X filed Jan. 2, 2025, the disclosure of which is incorporated herein by reference in its entirety.

### TECHNICAL FIELD

This disclosure relates to the field of semiconductor technologies, for example, a semiconductor structure and a manufacturing method thereof.

### BACKGROUND

A high-electron-mobility transistor (HEMT) is a field-effect transistor that utilizes a heterojunction formed by two materials with different bandgaps and provides a channel for carrier transport. When an HEMT operates, the gate region and the drain region of the HEMT are required to withstand a high electric field, but the drain region of the HEMT cannot effectively block electron transition to defects in the buffer layer or the passivation layer, resulting in a degradation of the dynamic performance of the HEMT under a high voltage. Moreover, the high electric field adjacent to the gate region causes reliability problems such as threshold voltage instability and gate breakdown.

### SUMMARY

In view of this, embodiments of this disclosure provide a semiconductor structure and a manufacturing method thereof to solve the problem in which the dynamic performance and reliability of a p-GaN HEMT device operating at a high voltage decrease in the related art.

According to an aspect of this disclosure, a semiconductor structure of an embodiment of this disclosure includes a substrate, a channel layer, and a barrier layer that are stacked in sequence; multiple first P-type semiconductor layers, and multiple second P-type semiconductor layers. The channel layer and the barrier layer include a gate region, and a source region and a drain region located on two sides of the gate region. The first P-type semiconductor layers are arranged along a first direction. The first P-type semiconductor layers are located on the side of the barrier layer facing away from the substrate and located in the gate region. The first direction is the extension direction of the gate region. The second P-type semiconductor layers are arranged along the first direction. The second P-type semiconductor layers are located on the side of the barrier layer facing away from the substrate and located between the gate region and the drain region. The first P-type semiconductor layers and the second P-type semiconductor layers alternate along the first direction.

According to another aspect of this disclosure, a manufacturing method of a semiconductor structure of an embodiment of this disclosure includes sequentially epitaxially forming a channel layer and a barrier layer on a substrate, where the channel layer and the barrier layer include a gate region, and a source region and a drain region located on two sides of the gate region; on the side of the barrier layer facing away from the substrate, epitaxially forming a P-type semiconductor material layer in the gate region and between the gate region and the drain region; and activating the P-type semiconductor material layer to form multiple first P-type semiconductor layers arranged along a first direction and multiple second P-type semiconductor layers arranged along the first direction, where the first P-type semiconductor layers are located in the gate region, the second P-type semiconductor layers are located between the gate region and the drain region, the first direction is the extension direction of the gate region, and the first P-type semiconductor layers and the second P-type semiconductor layers alternate along the first direction.

### BRIEF DESCRIPTION OF DRAWINGS

FIG. 1 is a diagram illustrating the structure of a semiconductor structure according to an embodiment of this disclosure.

FIG. 2 is a section view taken along AA′ of the semiconductor structure of FIG. 1.

FIG. 3 is a section view taken along BB′ of the semiconductor structure of FIG. 1.

FIG. 4 is a section view taken along CC′ of the semiconductor structure of FIG. 1.

FIG. 5 is a diagram illustrating the structure of a semiconductor structure according to an embodiment of this disclosure.

FIG. 6 is a section view taken along DD′ of the semiconductor structure of FIG. 5.

FIG. 7 is a section view taken along EE′ of the semiconductor structure of FIG. 5.

FIG. 8 is a section view taken along FF′ of the semiconductor structure of FIG. 5.

FIG. 9 is a diagram illustrating the structure of a semiconductor structure according to an embodiment of this disclosure.

FIG. 10 is a diagram illustrating the structure of a semiconductor structure according to an embodiment of this disclosure.

FIG. 11 is a diagram illustrating the structure of a semiconductor structure according to an embodiment of this disclosure.

FIG. 12 is a diagram illustrating the structure of a semiconductor structure according to an embodiment of this disclosure.

FIG. 13 is a diagram illustrating the structure of a semiconductor structure according to an embodiment of this disclosure.

FIG. 14 is a diagram illustrating the structure of a semiconductor structure according to an embodiment of this disclosure.

FIG. 15 is a diagram illustrating the structure of a semiconductor structure according to an embodiment of this disclosure.

FIG. 16 to FIG. 25 are each a diagram illustrating the structure of intermediate structures during manufacturing a semiconductor structure according to an embodiment of this disclosure.

FIG. 26 is a diagram illustrating the structure of a semiconductor structure according to an embodiment of this disclosure.

FIG. 27 is a diagram illustrating the structure of a semiconductor structure according to an embodiment of this disclosure.

### DETAILED DESCRIPTION

Solutions in embodiments of this disclosure are described clearly and completely hereinafter in conjunction with the drawings in embodiments of this disclosure. Apparently, the embodiments described hereinafter are part, not all, of embodiments of this disclosure.

This disclosure provides a semiconductor structure and a manufacturing method thereof. The semiconductor structure includes a substrate, a channel layer, and a barrier layer that are stacked in sequence; multiple first P-type semiconductor layers, and multiple second P-type semiconductor layers. The channel layer and the barrier layer include a gate region, and a source region and a drain region located on two sides of the gate region. The first P-type semiconductor layers are arranged along a first direction. The first P-type semiconductor layers are located on the side of the barrier layer facing away from the substrate and located in the gate region. The first direction is the extension direction of the gate region. The second P-type semiconductor layers are arranged along the first direction. The second P-type semiconductor layers are located on the side of the barrier layer facing away from the substrate and located between the gate region and the drain region. The first P-type semiconductor layers and the second P-type semiconductor layers alternate along the first direction.

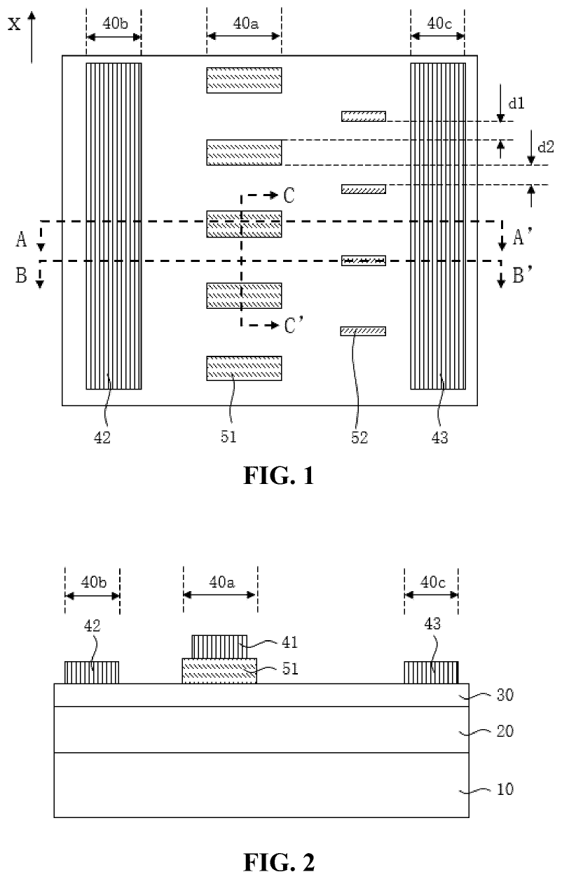

The following describes the semiconductor structure and the manufacturing method with reference to FIG. 1 to FIG. 26.

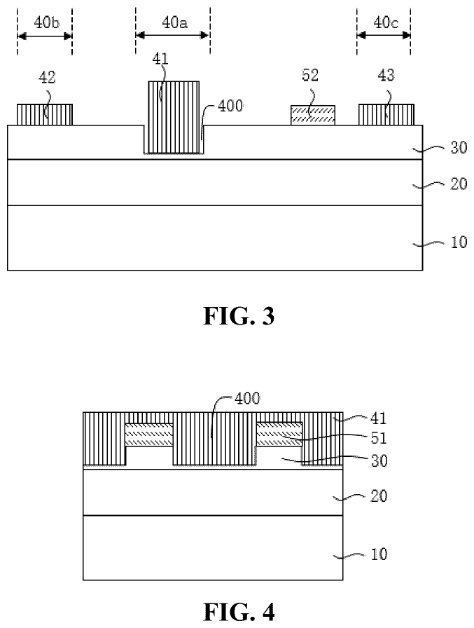

FIG. 1 is a diagram illustrating the structure of a semiconductor structure according to an embodiment of this disclosure. FIG. 2 is a section view taken along AA′ of the semiconductor structure of FIG. 1. FIG. 3 is a section view taken along BB′ of the semiconductor structure of FIG. 1. As shown in FIG. 1 to FIG. 3, the semiconductor structure includes a substrate 10, a channel layer 20, and a barrier layer 30 that are stacked in sequence; multiple first P-type semiconductor layers 51, and multiple second P-type semiconductor layers 52. The channel layer 20 and the barrier layer 30 include a gate region 40a and a source region 40b and a drain region 40c located on two sides of the gate region 40a. The first P-type semiconductor layers 51 are arranged along a first direction X. The first P-type semiconductor layers 51 are located on the side of the barrier layer 30 facing away from the substrate 10 and located in the gate region 40a. The first direction X is the extension direction of the gate region 40a. The second P-type semiconductor layers 52 are arranged along the first direction X. The second P-type semiconductor layers 52 are located on the side of the barrier layer 30 facing away from the substrate 10 and located between the gate region 40a and the drain region 40c. The first P-type semiconductor layers 51 and the second P-type semiconductor layers 52 alternate along the first direction X.

Specifically, the channel layer 20 and the barrier layer 30 form a heterojunction. A two-dimensional electron gas (2DEG) channel is formed on the surface of the channel layer 20 close to the barrier layer 30.

Specifically, the first P-type semiconductor layers 51 are located in the gate region 40a and spaced apart along the first direction X, alleviating electric field crowding in the gate region, improving the gate breakdown voltage of the device, increasing the swing of the gate voltage, and improving the linearity and gate control capability of the device. Moreover, the second P-type semiconductor layers 52 are located between the gate region 40a and the drain region 40c and spaced apart along the first direction X to provide a smooth electric field distribution for a side of the gate close to the drain, reducing current collapse. In addition, the first P-type semiconductor layers 51 and the second P-type semiconductor layers 52 alternate along the first direction X. In other words, there is a gap between two adjacent first P-type semiconductor layers 51, and the projection of the gap on a first plane coincides with the projection of one second P-type semiconductor layer 52 on the first plane. The first plane is perpendicular to the plane where the substrate 10 is located and parallel to the first direction X. Thus, the first P-type semiconductor layers 51 and the second P-type semiconductor layers 52 alternate along the extension direction of the first plane in the first direction X. The P-type semiconductor layers alternate in two regions. Thus, for different regions along the first direction X, regions through which two-dimensional electron gas that transitions during the operation of the device passes involve similar resistance, enabling a more uniform current distribution of the device and avoiding local overheating caused by current blocking.

Optionally, when the total projected area of all the first P-type semiconductor layers 51 on the substrate 10 is greater than the total projected area of all the second P-type semiconductor layers 52 on the substrate 10 or when the P-type doping concentration of the first P-type semiconductor layers 51 is higher than the P-type doping concentration of the second P-type semiconductor layers 52, the number of P-type carriers of the second P-type semiconductor layers 52 is small, reducing the drain-source capacitance and the drain-gate capacitance and allowing the device to operate at a high speed.

Optionally, the first P-type semiconductor layers 51 and the second P-type semiconductor layers 52 are simultaneously epitaxially formed on the barrier layer 30, and in the direction perpendicular to the plane where the substrate 10 is located, the thickness of the first P-type semiconductor layer 51 is equal to the thickness of the second P-type semiconductor layer 52.

Optionally, the semiconductor structure also includes a nucleation layer and a buffer layer located between the substrate 10 and the channel layer 20. The nucleation layer provides a nucleation site for epitaxy in subsequent manufacturing of the channel layer 20. The buffer layer is configured to alleviate lattice mismatch between the substrate 10 and the channel layer 20 to improve crystal quality of a subsequent epitaxial structure.

It is to be noted that to illustrate the first P-type semiconductor layer 51, the gate 41 of the gate region 40a is not illustrated in FIG. 1.

In an embodiment, along the first direction X, the distance between a first P-type semiconductor layer 51 and a second P-type semiconductor layer 52 adjacent to each other is greater than 0. Specifically, as shown in FIG. 1, along the first direction X, there is one second P-type semiconductor layer 52 on one side of the first P-type semiconductor layer 51 and one second P-type semiconductor layer 52 on the other side of the first P-type semiconductor layer 51. The distance between the first P-type semiconductor layer 51 and one of the second P-type semiconductor layers 52 is d1. d1>0. The distance between the first P-type semiconductor layer 51 and the other of the second P-type semiconductor layers 52 is d2. d2>0. Thus, along the first direction X, an increase in the distance between the first P-type semiconductor layer 51 and the second P-type semiconductor layer 52 adjacent to each other can improve the current uniformity of the device and avoid local overheating caused by current blocking.

Optionally, in two adjacent groups of first P-type semiconductor layer 51 and second P-type semiconductor layer 52, d1=d2. The first P-type semiconductor layers 51 and the second P-type semiconductor layers 52 are arranged regularly.

In an embodiment, as shown in FIG. 1, along the first direction X, the first P-type semiconductor layers 51 are equally spaced, and the second P-type semiconductor layers 52 are equally spaced. In conjunction with d1=d2, the P-type semiconductor layers in the semiconductor structure are arranged regularly, better improving the current uniformity of the device and avoiding local overheating caused by current blocking.

In an embodiment, as shown in FIG. 1, along the first direction X, the width of the first P-type semiconductor layer 51 is greater than the width of the second P-type semiconductor layer 52. Specifically, the width of the second P-type semiconductor layer 52 along the first direction X is as small as possible to reduce its influence on the performance of the device.

In an embodiment, as shown in FIG. 2 and FIG. 3, the semiconductor structure also includes a gate 41 located in the gate region 40a and located on the side of the barrier layer 30 facing away from the substrate 10 and the side of the first P-type semiconductor layers 51 facing away from the substrate 10; a source 42 located in the source region 40b and located on the side of the channel layer 20 facing away from the substrate 10; and a drain 43 located in the drain region 40c and located on the side of the channel layer 20 facing away from the substrate 10.

In an embodiment, FIG. 4 is a schematic cross-sectional view of a CC′ section of the semiconductor structure provided in FIG. 1, and as shown in FIG. 4, a recess deep into the barrier layer 30 is included between two adjacent first P-type semiconductor layers 51, and the gate 41 covers the first P-type semiconductor layer 51 and the recess.

Specifically, as shown in FIG. 4, the first P-type semiconductor layers 51 are spaced apart in the following manner: The P-type semiconductor material layer is etched to form multiple recesses 400. The first P-type semiconductor layers 51 alternate with the recesses 400. In the gate region corresponding to the first P-type semiconductor layers 51, the first P-type semiconductor layers 51 can deplete the 2DEG at the underlying channel. In the gate region corresponding to the recesses 400, the recesses 400 penetrate into the barrier layer 30. The barrier layer 30 is thin so that the 2DEG density in the channel can be reduced. The first P-type semiconductor layers 51 alternate with the recesses 400 so that the channel located in the gate region 40a is pinched off at a zero gate voltage, thereby achieving an enhanced device.

It is to be noted that as shown in FIG. 4, the gate 41 covers the barrier layer 30 and exposed upper and side surfaces of a corresponding first P-type semiconductor layer 51 so that the gate has different resistances and threshold voltages at different positions, thereby enlarging the transconductance platform of the device and improving the linearity.

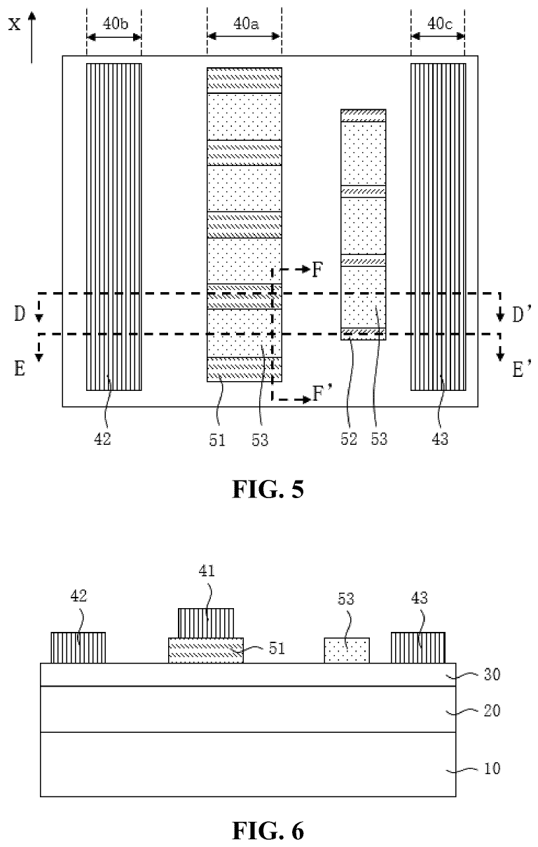

In an embodiment, FIG. 5 is a diagram illustrating the structure of a semiconductor structure according to an embodiment of this disclosure. As shown in FIG. 5, the semiconductor structure also includes an unactivated semiconductor layer 53 between two adjacent first P-type semiconductor layers 51.

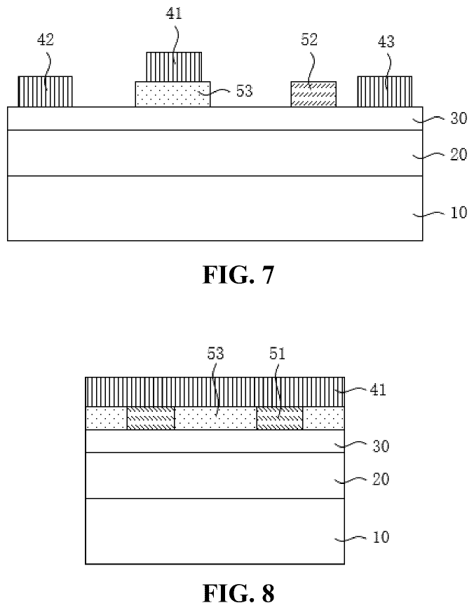

Specifically, FIG. 6 is a section view taken along DD′ of the semiconductor structure of FIG. 5, FIG. 7 is a section view taken along EE′ of the semiconductor structure of FIG. 5, and FIG. 8 is a section view taken along FF′ of the semiconductor structure of FIG. 5. As shown in FIG. 5 to FIG. 8, the first P-type semiconductor layers 51 are spaced apart in the following manner: Region activation is performed on the P-type semiconductor material layer. The first P-type semiconductor layers 51 are located in the activated region. The unactivated semiconductor layers 53 are located outside the activated region. The first P-type semiconductor layers 51 alternate with the unactivated semiconductor layers 53. In the subsequent process, the gate 41 is formed on the side of the first P-type semiconductor layers 51 and the unactivated semiconductor layers 53 facing away from the substrate 10, and the unactivated semiconductor layers 53 are not required to be removed by etching, thereby simplifying the manufacturing process and reducing the influence of the etching process on the device.

Optionally, as shown in FIG. 5 and FIG. 6, in section DD′, an unactivated semiconductor layer 53 is included between two adjacent second P-type semiconductor layers 52. Specifically, the P-type semiconductor material layer is subjected to region activation to form second P-type semiconductor layers 52 spaced apart.

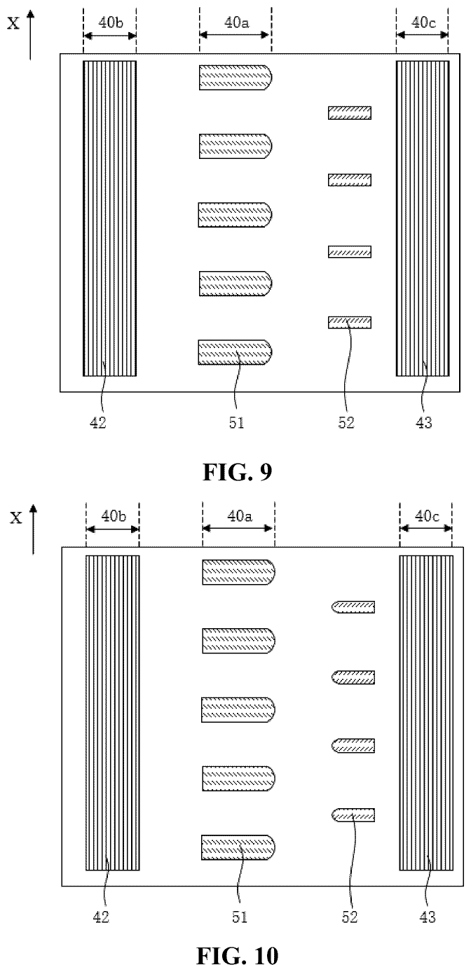

In an embodiment, FIG. 9 is a diagram illustrating the structure of a semiconductor structure according to an embodiment of this disclosure. As shown in FIG. 9, the projection of the end face of the first P-type semiconductor layer 51 close to the drain region 40c on the substrate 10 is an arc-shaped surface, better reducing the electric field crowding on the side of the gate region close to the drain region.

Optionally, FIG. 10 is a diagram illustrating the structure of a semiconductor structure according to an embodiment of this disclosure. As shown in FIG. 10, the projection of the end face of the first P-type semiconductor layer 51 close to the drain region 40c on the substrate 10 is an arc-shaped surface, and the projection of the end face of the second P-type semiconductor layer 52 close to the gate region 40a on the substrate 10 is an arc-shaped surface, better reducing the electric field crowding on the side of the gate region close to the drain region.

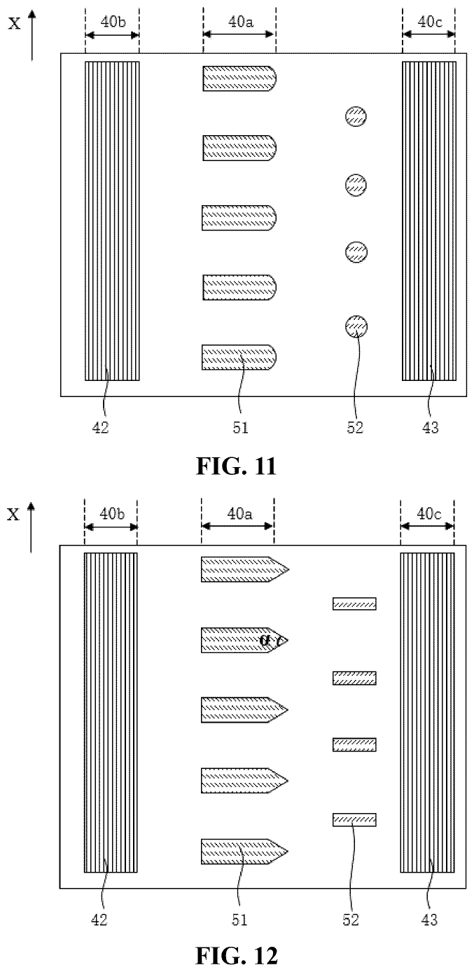

Optionally, FIG. 11 is a diagram illustrating the structure of a semiconductor structure according to an embodiment of this disclosure. As shown in FIG. 11, the projection of the second P-type semiconductor layer 52 on the substrate 10 is circular, better reducing the electric field crowding on the side of the gate region close to the drain region.

In an embodiment, FIG. 12 is a diagram illustrating the structure of a semiconductor structure according to an embodiment of this disclosure. As shown in FIG. 12, the shape of the projection of the end face of the first P-type semiconductor layer 51 close to the drain region 40c on the substrate 10 includes at least one included angle α. Specifically, when the number of included angles is 1, the shape of the projection of one end of the first P-type semiconductor layer 51 on the substrate 10 may be considered as a triangle. In this case, the included angle α should be greater than or equal to 45°, avoiding electric field crowding caused by a too small included angle. Optionally, when the number of the included angles is 2, as shown in FIG. 1, the shape of the projection of one end of the first P-type semiconductor layer 51 on the substrate 10 may be considered as a rectangle. Optionally, the larger the number of included angles, the closer the shape of the projection of one end of the first P-type semiconductor layer 51 on the substrate 10 is to an arc, improving the electric field crowding.

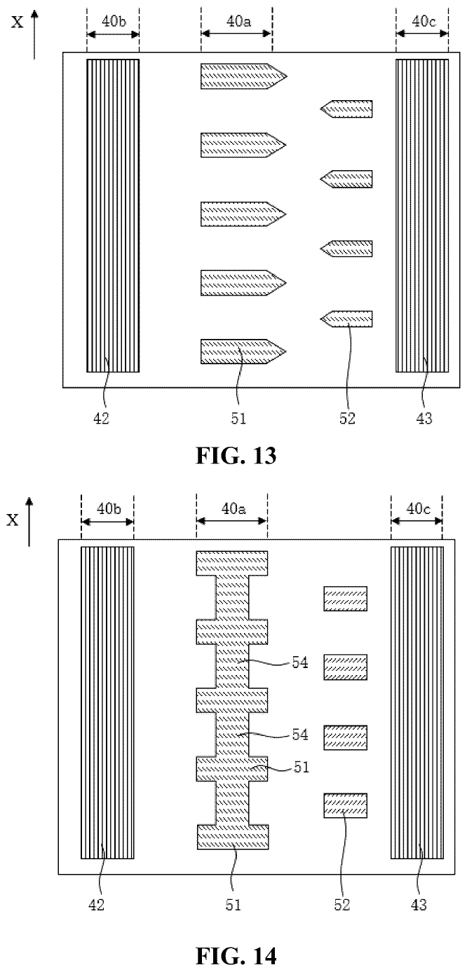

In an embodiment, FIG. 13 is a diagram illustrating the structure of a semiconductor structure according to an embodiment of this disclosure. As shown in FIG. 13, the shape of the projection of the end face of the first P-type semiconductor layer 51 close to the drain region 40c on the substrate 10 is a triangle, and the shape of the projection of the end face of the second P-type semiconductor layer 52 close to the gate region 40a on the substrate 10 is a triangle.

In an embodiment, FIG. 14 is a diagram illustrating the structure of a semiconductor structure according to an embodiment of this disclosure. As shown in FIG. 14, the semiconductor structure also includes a first P-type connection portion 54 connecting two adjacent first P-type semiconductor layers 51. In a second direction Y, the width of the first P-type semiconductor layer 51 is greater than the width of the first P-type connection portion 54. The second direction Y is perpendicular to the first direction X and parallel to the plane where the substrate 10 is located. Specifically, the first P-type semiconductor layer 51 and the first P-type connection portion 54 jointly deplete the 2DEG at the underlying channel to achieve an enhanced device. The first P-type semiconductor layer 51 extends towards the drain region 40c, alleviating the electric field crowding in the gate region.

In an embodiment, the ratio of the projected area of a first P-type semiconductor layer 51 on the gate 41 to the projected area of the gate 41 on the substrate 10 is greater than or equal to 50%, maintaining a certain p-type gate hole concentration and ensuring the gate control capability of the device. Optionally, the distance between two adjacent first P-type semiconductor layers 51 is less than or equal to 3 μm.

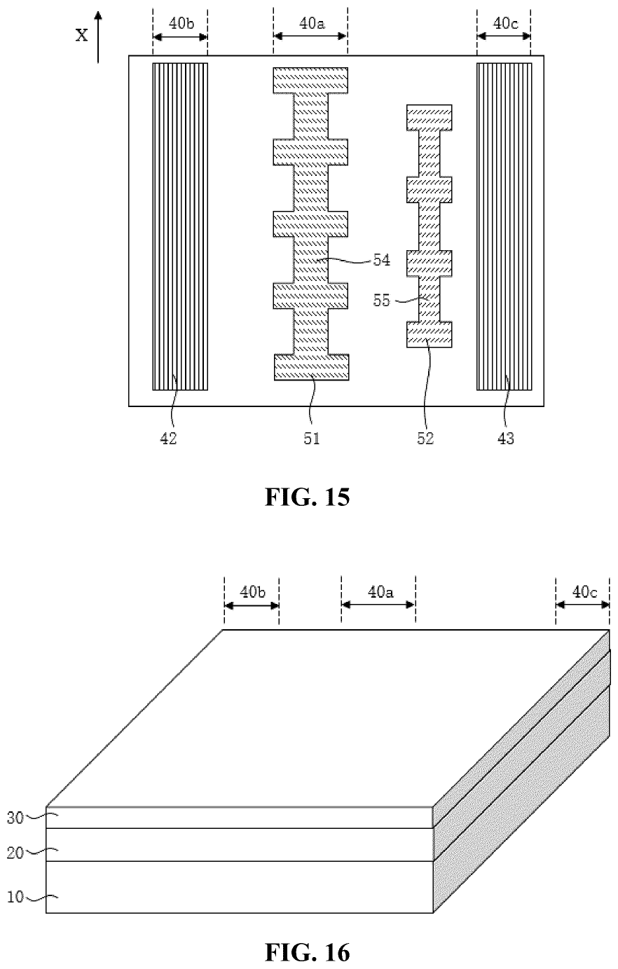

In an embodiment, FIG. 15 is a diagram illustrating the structure of a semiconductor structure according to an embodiment of this disclosure. As shown in FIG. 15, the semiconductor structure also includes a second P-type connection portion 55 connecting two adjacent second P-type semiconductor layers 52. In the second direction Y, the width of the second P-type semiconductor layer 52 is greater than the width of the second P-type connection portion 55, ensuring current uniformity along the first direction X.

In an embodiment, this disclosure provides a manufacturing method of a semiconductor structure. FIG. 16 to FIG. 25 are each a diagram illustrating the structure of intermediate structures during manufacturing a semiconductor structure according to an embodiment of this disclosure. The manufacturing method includes the following steps:

In step S1, as shown in FIG. 16, a channel layer 20 and a barrier layer 30 are sequentially epitaxially formed above a substrate 10, where the channel layer 20 and the barrier layer 30 include a gate region 40a and a source region 40b and a drain region 40c located on two sides of the gate region 40a. Specifically, before the channel layer 20 is formed, a nucleation layer and a buffer layer are preferably epitaxially formed on the substrate 10.

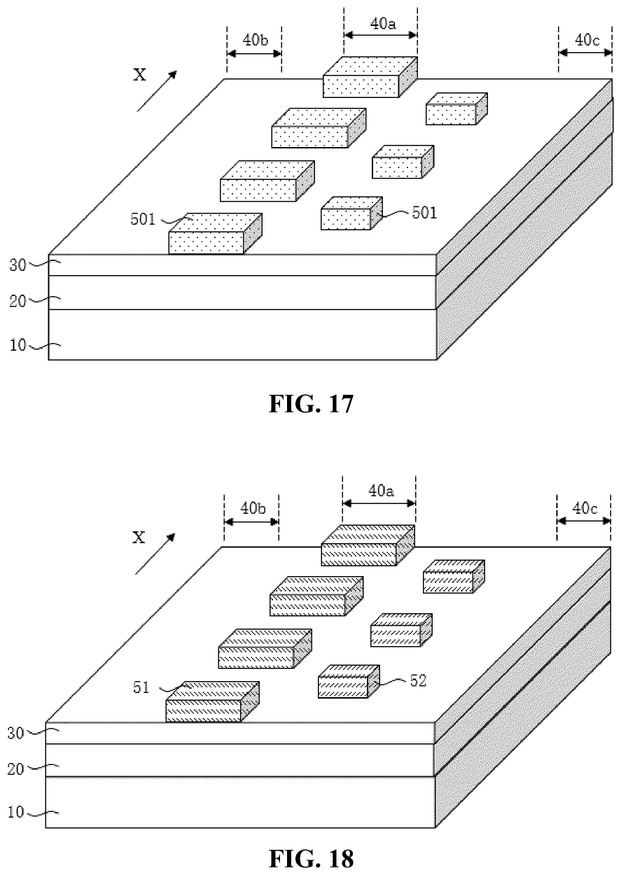

In step S2, as shown in FIG. 17, on the side of the barrier layer 30 facing away from the substrate 10, a P-type semiconductor material layer 501 is epitaxially formed in the gate region 40a and between the gate region 40a and the drain region 40c. Optionally, the P-type semiconductor material layer 501 is formed on the barrier layer 30 by selective epitaxy.

In step S3, as shown in FIG. 18, the P-type semiconductor material layer 501 is activated to form multiple first P-type semiconductor layers 51 arranged along a first direction X and multiple second P-type semiconductor layers 52 arranged along the first direction X. The first P-type semiconductor layers 51 are located in the gate region 40a. The second P-type semiconductor layers 52 are located between the gate region 40a and the drain region 40c. The first direction X is the extension direction of the gate region 40a. The first P-type semiconductor layers 51 and the second P-type semiconductor layers 52 alternate along the first direction X.

Specifically, the first P-type semiconductor layers 51 are located in the gate region 40a and spaced apart along the first direction X, alleviating electric field crowding in the gate region, improving the gate breakdown voltage of the device, increasing the swing of the gate voltage, and improving the linearity and gate control capability of the device. The second P-type semiconductor layers 52 are located between the gate region 40a and the drain region 40c and spaced apart along the first direction X to provide a smooth electric field distribution for a side of the gate close to the drain, reducing current collapse. The first P-type semiconductor layers 51 and the second P-type semiconductor layers 52 alternate along the first direction, enabling a more uniform current distribution of the device and avoiding local overheating caused by current blocking.

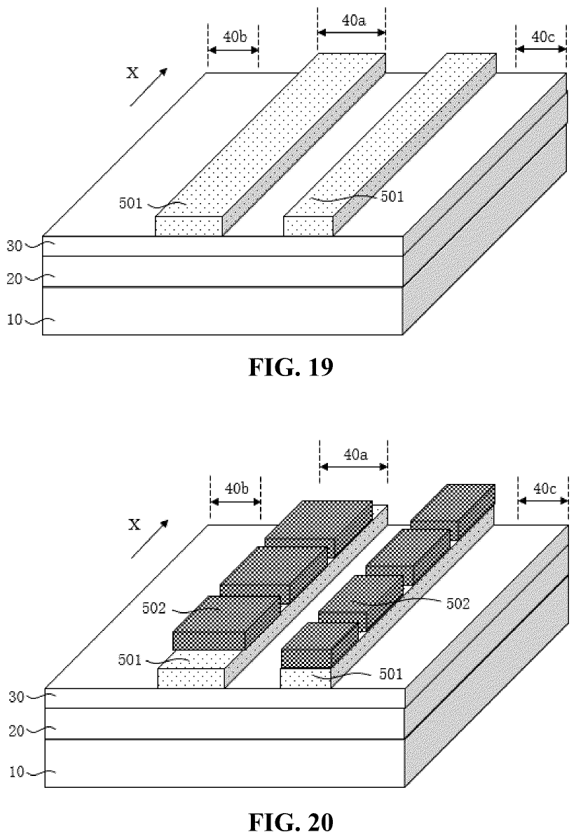

In an embodiment, as shown in FIG. 19, the P-type semiconductor material layer 501 extends along the first direction X, the P-type semiconductor material layer 501 is strip-shaped, and activating the P-type semiconductor material layer 501 includes the following:

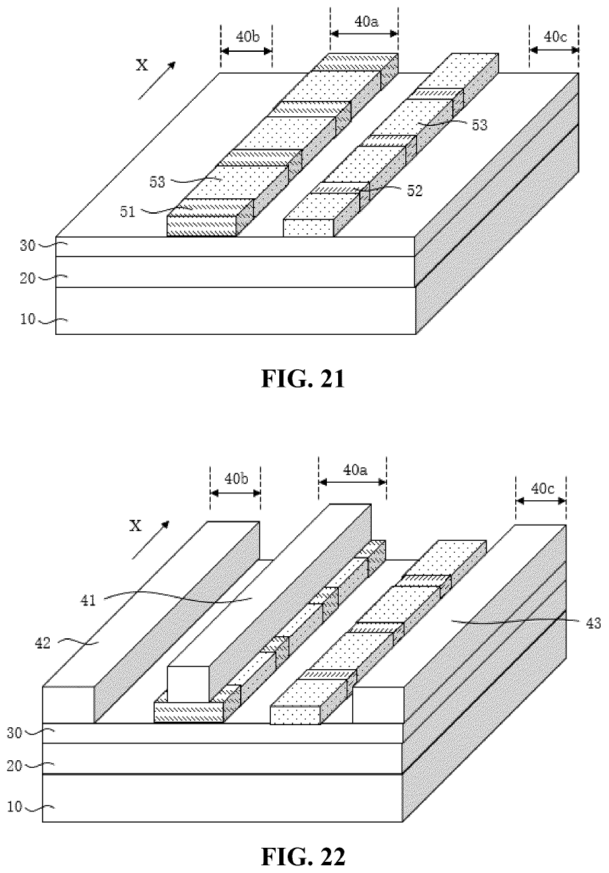

As shown in FIG. 21, the P-type semiconductor material layer 501 is regionally activated to form the first P-type semiconductor layers 51 and unactivated semiconductor layers 53 that alternate in the gate region 40a and form the second P-type semiconductor layers 52 and unactivated semiconductor layers 53 that alternate between the gate region 40a and the drain region 40c.

Optionally, as shown in FIG. 20, a patterned mask layer 502 is formed on the P-type semiconductor material layer 501. The region covered by the mask layer 502 prevents H atoms from overflowing during the activation process. The H atoms are combined with Mg atoms. An unactivated semiconductor layer 53 is formed below. The region not covered by the mask layer 502 has less influence on overflowing of the H atoms during the activation process. The Mg atoms are released. Localized activation is performed to form the first P-type semiconductor layers 51 and the second P-type semiconductor layers 52. In the subsequent process, the mask layer 502 is removed by etching to obtain an intermediate structure as shown in FIG. 21.

Optionally, as shown in FIG. 22 and FIG. 4, a gate 41 is formed in the gate region 40a, a source 42 is formed in the source region 40b, and a drain 43 is formed in the drain region 40c.

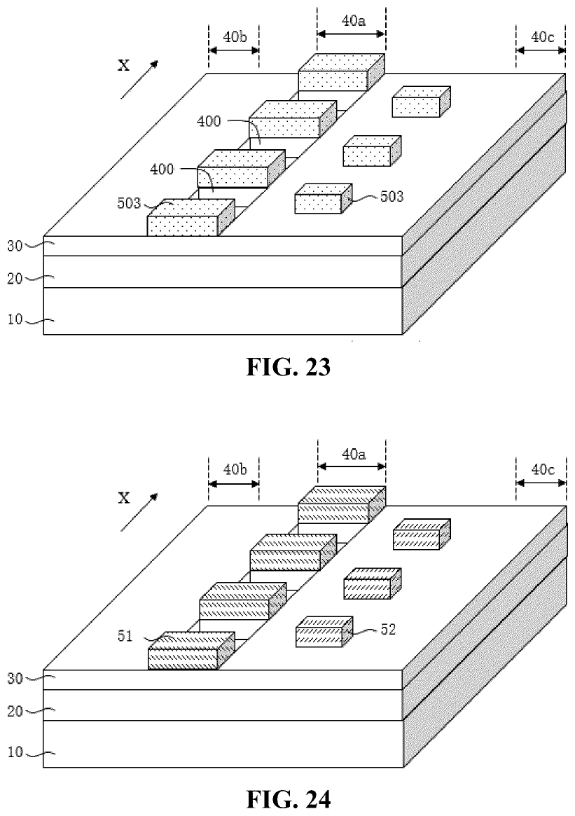

In an embodiment, after the P-type semiconductor material layer is epitaxially formed, the method also includes the following:
As shown in FIG. 10 and FIG. 23, the P-type semiconductor material layer 501 is pattern-etched to form semiconductor intermediate layers 503 spaced apart along the first direction X. A recess 400 is formed between two adjacent semiconductor intermediate layers 503. The recess 400 penetrates into the barrier layer 30. Optionally, as shown in FIG. 23, no recess is formed between adjacent semiconductor intermediate layers 503 located between the gate region 40a and the drain region 40c as no etching is performed.

As shown in FIG. 24, the semiconductor intermediate layers 503 are activated to form the first P-type semiconductor layers 51 and the second P-type semiconductor layers 52.

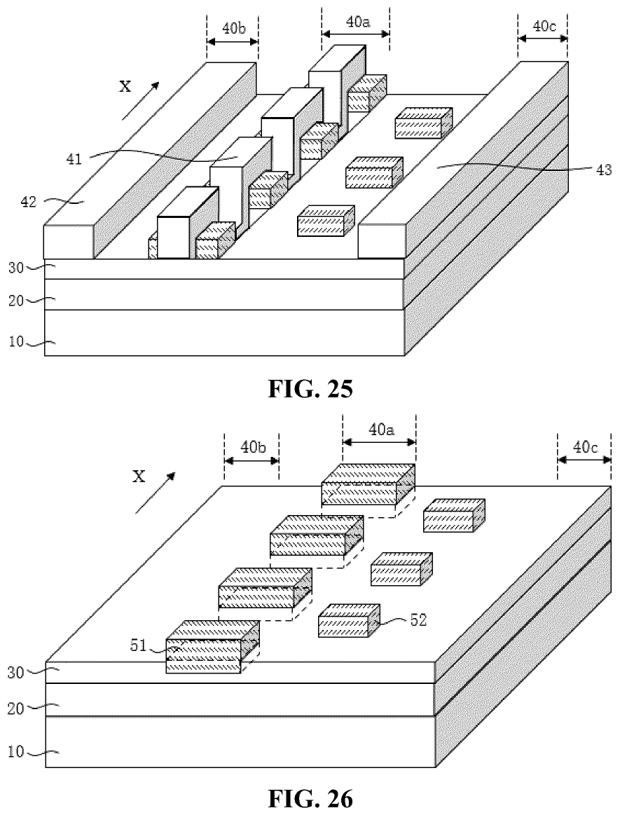

As shown in FIG. 25, the manufacturing method also includes forming a gate 41 in the gate region 40a. the gate covers the first P-type semiconductor layer 51 and the recess 400. Optionally, the manufacturing method also includes forming a source 42 in the source region 40b and forming a drain 43 in the drain region 40c.

In an embodiment, FIG. 26 is a diagram illustrating the structure of a semiconductor structure according to an embodiment of this disclosure. As shown in FIG. 26, part of the first P-type semiconductor layer 51 is located in the barrier layer 30 so that the thickness of the barrier layer 30 under the first P-type semiconductor layer 51 is less than the thickness of the barrier layer 30 under the second P-type semiconductor layer 52. The first P-type semiconductor layer 51 located in the gate region 40 a is closer to the channel and closer to the 2DEG, thereby improving the threshold voltage. Moreover, the electric field on the sidewall of the gate is optimized, thereby improving the gate breakdown voltage.

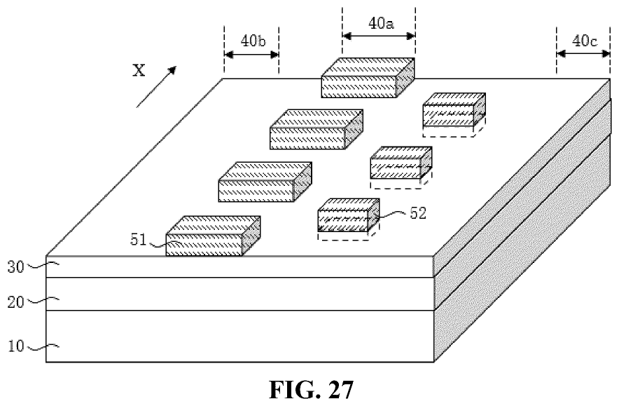

In an embodiment, FIG. 27 is a diagram illustrating the structure of a semiconductor structure according to an embodiment of this disclosure. As shown in FIG. 27, part of the second P-type semiconductor layer 52 is located in the barrier layer 30 so that the thickness of the barrier layer 30 under the first P-type semiconductor layer 51 is greater than the thickness of the barrier layer 30 under the second P-type semiconductor layer 52. The second P-type semiconductor layer 52 located between the gate region 40a and the drain region 40c is closer to the channel and closer to the leakage electrons. The second P-type semiconductor layer 52 has a stronger ability to deplete the leakage electrons, thereby improving the dynamic performance of the device.

Optionally, after the barrier layer 30 is formed, the barrier layer 30 is selectively etched. A partial region of the barrier layer 30 is thinned. Then P-type semiconductor layers are formed in the thinned region by secondary epitaxy, breaking through the performance bottleneck of the existing primary epitaxy. Optionally, part of the first P-type semiconductor layers 51 and part of the second P-type semiconductor layers 52 are both located within the barrier layer 30. In this embodiment, the relative thicknesses of the first P-type semiconductor layer 51 and the relative thicknesses of the second P-type semiconductor layer 52 are not limited, and the thickness of the barrier layer 30 under the first P-type semiconductor layer 51 and the thickness of the barrier layer 30 under the second P-type semiconductor layer 52 are not limited.

It is to be understood that the term “include” and variations thereof are intended to be inclusive, that is, “including, but not limited to”. The term “an embodiment” indicates “at least one embodiment”. Herein, the described features, structures, materials, or characteristics can be combined in an appropriate manner in any one or more embodiments or examples. In addition, the different embodiments or examples described in this specification and the features of the different embodiments or examples can be combined by those skilled in the art on the condition that these embodiments or examples do not contradict each other.

What is claimed is:

1. A semiconductor structure, comprising:
a substrate, a channel layer, and a barrier layer stacked in sequence, wherein the channel layer and the barrier layer comprise a gate region, and a source region and a drain region located on two sides of the gate region;
a plurality of first P-type semiconductor layers arranged along a first direction, wherein the plurality of first P-type semiconductor layers are located on a side of the barrier layer facing away from the substrate and located in the gate region, and the first direction is an extension direction of the gate region; and
a plurality of second P-type semiconductor layers arranged along the first direction, wherein the plurality of second P-type semiconductor layers are located on the side of the barrier layer facing away from the substrate and located between the gate region and the drain region;
wherein the plurality of first P-type semiconductor layers and the plurality of second P-type semiconductor layers alternate along the first direction.

2. The semiconductor structure of claim 1, wherein among the plurality of first P-type semiconductor layers and the plurality of second P-type semiconductor layers, a distance between a first P-type semiconductor layer and a second P-type semiconductor layer adjacent to each other is greater than 0 along the first direction.

3. The semiconductor structure of claim 2, wherein along the first direction, the plurality of first P-type semiconductor layers are equally spaced, and the plurality of second P-type semiconductor layers are equally spaced.

4. The semiconductor structure of claim 3, wherein along the first direction, a width of the first P-type semiconductor layer is greater than a width of the second P-type semiconductor layer.

5. The semiconductor structure of claim 1, wherein among the plurality of first P-type semiconductor layers, a projection of an end face of a first P-type semiconductor layer close to the drain region on the substrate is an arc-shaped surface.

6. The semiconductor structure of claim 5, wherein among the plurality of second P-type semiconductor layers, a projection of an end face of a second P-type semiconductor layer close to the gate region on the substrate is an arc-shaped surface.

7. The semiconductor structure of claim 1, wherein among the plurality of first P-type semiconductor layers, a shape of a projection of an end face of a first P-type semiconductor layer close to the drain region on the substrate comprises at least one included angle.

8. The semiconductor structure of claim 7, wherein among the plurality of second P-type semiconductor layers, a shape of a projection of an end face of a second P-type semiconductor layer close to the gate region on the substrate comprises at least one included angle.

9. The semiconductor structure of claim 7, wherein the included angle is greater than or equal to 45°.

10. The semiconductor structure of claim 1, further comprising: a first P-type connection portion connecting two adjacent first P-type semiconductor layers among the plurality of first P-type semiconductor layers,
wherein among the plurality of first P-type semiconductor layers, in a second direction, a width of a first P-type semiconductor layer is greater than a width of the first P-type connection portion, and the second direction is perpendicular to the first direction and parallel to a plane where the substrate is located.

11. The semiconductor structure of claim 10, further comprising: a second P-type connection portion connecting two adjacent second P-type semiconductor layers among the plurality of second P-type semiconductor layers,
wherein among the plurality of second P-type semiconductor layers, in the second direction, a width of a second P-type semiconductor layer is greater than a width of the second P-type connection portion.

12. The semiconductor structure of claim 1, further comprising an unactivated semiconductor layer located between two adjacent first P-type semiconductor layers among the plurality of first P-type semiconductor layers.

13. The semiconductor structure of claim 1, further comprising:
a gate located in the gate region and located on a side of the barrier layer facing away from the substrate and a side of a first P-type semiconductor layer of the plurality of first P-type semiconductor layers facing away from the substrate;
a source located in the source region and located on a side of the channel layer facing away from the substrate; and
a drain located in the drain region and located on the side of the channel layer facing away from the substrate.

14. The semiconductor structure of claim 13, wherein a ratio of a projected area of the first P-type semiconductor layer on the gate to a projected area of the gate on the substrate is greater than or equal to 50%.

15. The semiconductor structure of claim 13, wherein among the plurality of first P-type semiconductor layers, a recess penetrating into the barrier layer is formed between two adjacent first P-type semiconductor layers; and the recess and the two adjacent first P-type semiconductor layers are covered by the gate.

16. The semiconductor structure of claim 1, wherein in a direction perpendicular to a plane where the substrate is located, thickness of a first P-type semiconductor layer of the plurality of first P-type semiconductor layers is equal to thickness of a second P-type semiconductor layer of the plurality of second P-type semiconductor layers.

17. The semiconductor structure of claim 1, wherein a total projected area of all the first P-type semiconductor layers on the substrate is greater than a total projected area of all the second P-type semiconductor layers on the substrate.

18. A manufacturing method of a semiconductor structure, comprising:
sequentially epitaxially forming a channel layer and a barrier layer on a substrate, wherein the channel layer and the barrier layer comprise a gate region, and a source region and a drain region located on two sides of the gate region;
on a side of the barrier layer facing away from the substrate, epitaxially forming a P-type semiconductor material layer in the gate region and between the gate region and the drain region; and
activating the P-type semiconductor material layer to form a plurality of first P-type semiconductor layers arranged along a first direction and a plurality of second P-type semiconductor layers arranged along the first direction, wherein the plurality of first P-type semiconductor layers are located in the gate region, the plurality of second P-type semiconductor layers are located between the gate region and the drain region, the first direction is an extension direction of the gate region, and the plurality of first P-type semiconductor layers and the plurality of second P-type semiconductor layers alternate along the first direction.

19. The manufacturing method of claim 18, wherein the P-type semiconductor material layer extends along the first direction, and activating the P-type semiconductor material layer comprises:
regionally activating the P-type semiconductor material layer to form the plurality of first P-type semiconductor layers and a plurality of unactivated semiconductor layers that alternate in the gate region and form the plurality of second P-type semiconductor layers and a plurality of unactivated semiconductor layers that alternate between the gate region and the drain region.

20. The manufacturing method of claim 18, after epitaxially forming the P-type semiconductor material layer, the method further comprises:
pattern-etching the P-type semiconductor material layer to form semiconductor intermediate layers spaced apart along the first direction, wherein a recess is formed between two adjacent ones of the semiconductor intermediate layers, and the recess penetrates into the barrier layer; and
activating the semiconductor intermediate layers to form the plurality of first P-type semiconductor layers and the plurality of second P-type semiconductor layers; and
the manufacturing method further comprises:
forming a gate in the gate region, wherein, the gate covers a first P-type semiconductor layer of the plurality of first P-type semiconductor layers and the recess.
